(19) United States
(12) Patent Application Publication
(10) Pub. No.: US 2012/0202028 A1
(43) Pub. Date: Aug. 9, 2012

(54) CERAMIC MEMBER AND MANUFACTURING THEREOF

(76) Inventors: Yau-Hung Chiou, Taipei City (TW); Shu-Hui Fan, Hsinchu County (TW)

(21) Appl. No.: 13/117,640

(22) Filed: May 27, 2011

(30) Foreign Application Priority Data
Feb. 8, 2011 (TW) 100104196

(51) Int. Cl. B32B 18/00; C23C 16/06; C23C 16/02; B32B 9/04; C23C 16/50; B82Y 30/00; B82Y 40/00

(52) U.S. Cl. 428/213; 428/426; 428/336; 427/535; 977/891; 977/755

(57) ABSTRACT

The present invention discloses a ceramic member and a manufacturing method thereof. The ceramic member comprises a ceramic substrate and an intermediate layer. Wherein, the intermediate layer is disposed on the ceramic substrate by vacuum depositing, and the intermediate layer is a carbonized metal (MₓC_{y}), an oxidized metal (MₓO_{y}) or a nitride metal (MₓN_{y}). Preferably, the intermediate layer could have a concentration gradient or a thickness gradient to further increase the adhesion between the metal layer deposited on the ceramic substrate.

### FIELD

The exemplary embodiment(s) of the present invention relates to a field of a ceramic member and a manufacturing method thereof More specifically, the exemplary embodiment(s) of the present invention relates to a metal member having a carbonized metal layer with a concentration gradient or an oxidized metal layer with a concentration gradient and a manufacturing method thereof

### BACKGROUND

The conventional ceramic housing is often deposited a metal layer as a decorating layer. However, due to the highly difference of the crystal lattice between different materials, there is a high residual stress on the heterogeneous interface, and thus the decorating layer is easy to fall off from the ceramic housing, causing the appearance of the conventional consumer electronics being not tried-and-true.

The conventional method of depositing the metal film comprises electroplating and arc-deposition, however the adhesion ability of these metal films is not increased by these methods. Thus, providing a highly adhesion ability intermediate layer disposed between the metal decoration layer and the ceramic substrate and a manufacturing thereof is to brook no delay.

### SUMMARY

To solve the problems in the prior art, it is a primary object of the present invention to provide a ceramic member and a manufacturing thereof to solve the problem that the adhesion is insufficient between the ceramic housing and the metal deposited thereon.

To achieve the above object, a ceramic member according to the present invention is disclosed, which comprises a ceramic substrate and an intermediate layer. The intermediate layer is disposed on one side of the ceramic substrate by reactively vacuum deposition, and the intermediate layer is a carbonized metal (MₓC_{y}), an oxidized metal (MₓO_{y}) or a nitride metal (MₓN_{y}).

Wherein the intermediate layer further comprises a first sub-intermediate layer and a second sub-intermediate layer. The first sub-intermediate layer (MₐC_{b}) is disposed on the side of the ceramic substrate, and the second sub-intermediate layer (M_{c}C_{d}) is disposed on the first sub-intermediate. Wherein, a+b=1, c+d=1 and a<c.

Wherein the intermediate layer further comprises a first sub-intermediate layer and a second sub-intermediate layer. The first sub-intermediate layer (MₐO_{b}) is disposed on the side of the ceramic substrate, and the second sub-intermediate layer (M_{c}O_{d}) is disposed on the first sub-intermediate. Wherein, a+b=1, c+d=1 and a<c.

Wherein the intermediate layer further comprises a first sub-intermediate layer and a second sub-intermediate layer. The first sub-intermediate layer (MₐN_{b}) is disposed on the side of the ceramic substrate, and the second sub-intermediate layer (M_{c}N_{d}) is disposed on the first sub-intermediate. Wherein, a+b=1, c+d=1 and a<c.

Wherein the intermediate layer further comprises a first sub-intermediate layer and a second sub-intermediate layer. The first sub-intermediate layer is disposed on the side of the ceramic substrate, and the second sub-intermediate layer is disposed on the first sub-intermediate. Wherein, the thickness of the first sub-intermediate layer is less than the thickness of the second sub-intermediate layer.

Wherein the intermediate layer further comprises a first sub-intermediate layer and a second sub-intermediate layer. The first sub-intermediate layer is disposed on the side of the ceramic substrate, and the second sub-intermediate layer is disposed on the first sub-intermediate. Wherein, the thickness of the first sub-intermediate layer is higher than the thickness of the second sub-intermediate layer.

Wherein the thickness of the intermediate layer is 1˜500 nm.

Wherein the ceramic member further comprises a metal layer disposed on the intermediate layer.

To achieve another object, a ceramic member manufacturing method according to the present invention is disclosed, which comprises the following steps of: providing a ceramic substrate; bombarding one side of the ceramic substrate by plasma; and depositing an intermediate layer on the side of the ceramic substrate by reactively vacuum deposition, and the intermediate layer being a carbonized metal (MₓC_{y}), an oxidized metal (MₓO_{y}) or a nitride metal (MₓN_{y}).

Wherein the step of depositing the intermediate layer further comprises: depositing a first sub-intermediate layer (MₐC_{b}) on the side of the ceramic substrate; and depositing a second sub-intermediate layer (M_{c} C _{d}) on the first sub-intermediate layer. Wherein, a+b=1, c+d=1 and a<c.

Wherein the step of depositing the intermediate layer further comprises: depositing a first sub-intermediate layer (MₐO_{b}) on the side of the ceramic substrate; and depositing a second sub-intermediate layer (M_{c}O_{d}) on the first sub-intermediate layer. Wherein, a+b=1, c+d=1 and a<c.

Wherein the step of depositing the intermediate layer further comprises: depositing a first sub-intermediate layer (MₐN_{b}) on the side of the ceramic substrate; and depositing a second sub-intermediate layer (M_{c}N_{d}) on the first sub-intermediate layer. Wherein, a+b=1, c+d=1 and a<c.

Wherein the step of depositing the intermediate layer further comprises: depositing a first sub-intermediate layer on the side of the ceramic substrate; and depositing a second sub-intermediate layer on the first sub-intermediate layer. Wherein the thickness of the first sub-intermediate layer is less than the thickness of the second sub-intermediate layer.

Wherein the step of depositing the intermediate layer further comprises: depositing a first sub-intermediate layer on the side of the ceramic substrate; and depositing a second sub-intermediate layer on the first sub-intermediate layer. Wherein the thickness of the first sub-intermediate layer is higher than the thickness of the second sub-intermediate layer.

Wherein the working pressure of the plasma bombardment and the vacuum deposition is 10⁻²˜10⁻⁴ Pa.

Wherein the argon, organic gas, oxygen, nitrogen or a mixture of at least two gases mentioned is provided as the plasma gas during the vacuum deposition.

Wherein the organic gas is methane or acetylene.

Wherein the thickness of the intermediate layer is 1˜500 nm.

Wherein the ceramic member manufacturing method further comprises the step of: depositing a metal layer on the intermediate layer by vacuum deposition.

With the above arrangements, the ceramic member and the manufacturing method thereof according to the present invention has one or more of the following advantages:

(1) The adhesion of the metal films could be increased by disposing an intermediate layer between the ceramic substrate and the deposited metal layer in accordance with the present invention.

(2) The problem that the deposited metal layer could not be fixed on the ceramic substrate could be solved by gradually changing the concentration or the thickness of the intermediate layer in accordance with the present invention.

With these and other objects, advantages, and features of the invention that may become hereinafter apparent, the nature of the invention may be more clearly understood by reference to the detailed description of the invention, the embodiments and to the several drawings herein.

### BRIEF DESCRIPTION OF THE DRAWINGS

The exemplary embodiment(s) of the present invention will be understood more fully from the detailed description given below and from the accompanying drawings of various embodiments of the invention, which, however, should not be taken to limit the invention to the specific embodiments, but are for explanation and understanding only.

FIG. 1 illustrates a flow chart of the ceramic member manufacturing method in accordance with the present invention;

FIG. 2 illustrates another flow chart of the ceramic member manufacturing method thereof in accordance with the present invention;

FIG. 3 illustrates still another flow chart of the ceramic member manufacturing method in accordance with the present invention;

FIG. 4 illustrates a schematic diagram of the ceramic member manufacturing method in accordance with the present invention;

FIG. 5 illustrates a schematic diagram of the first embodiment of the ceramic member in accordance with the present invention;

FIG. 6 illustrates a schematic diagram of the second embodiment of the ceramic member in accordance with the present invention;

FIG. 7 illustrates a schematic diagram of the third embodiment of the ceramic member in accordance with the present invention; and

FIG. 8 illustrates a schematic diagram of the fourth embodiment of the ceramic member in accordance with the present invention.

### DETAILED DESCRIPTION

The exemplary embodiment(s) of the present invention will be understood more fully from the detailed description given below and from the accompanying drawings of various embodiments of the invention, which, however, should not be taken to limit the invention to the specific embodiments, but are for explanation and understanding only. For the purpose of being easy to understand, elements that are the same in the embodiments are denoted by the same reference numerals.

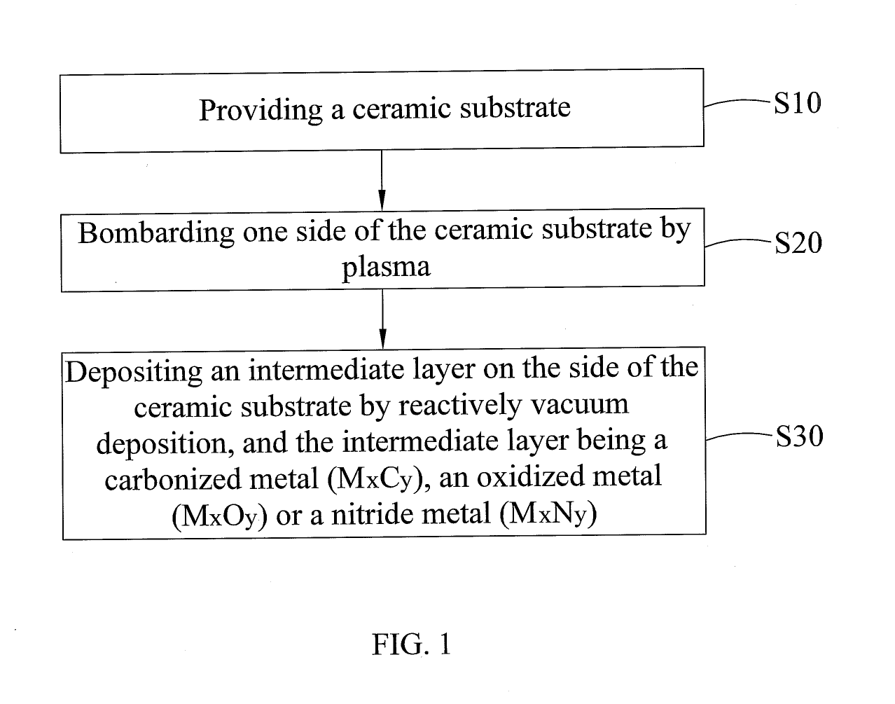

Please refer to FIG. 1, which illustrates a flow chart of the ceramic member manufacturing method in accordance with the present invention. As shown in this figure, the ceramic member manufacturing method in accordance with the present invention comprises the following steps of:

(S10) providing a ceramic substrate;

(S20) bombarding one side of the ceramic substrate by plasma; and

(S30) depositing an intermediate layer on the side of the ceramic substrate by reactively vacuum deposition, and the intermediate layer being a carbonized metal (MₓC_{y}), an oxidized metal (MₓO_{y}) or a nitride metal (MₓN_{y}).

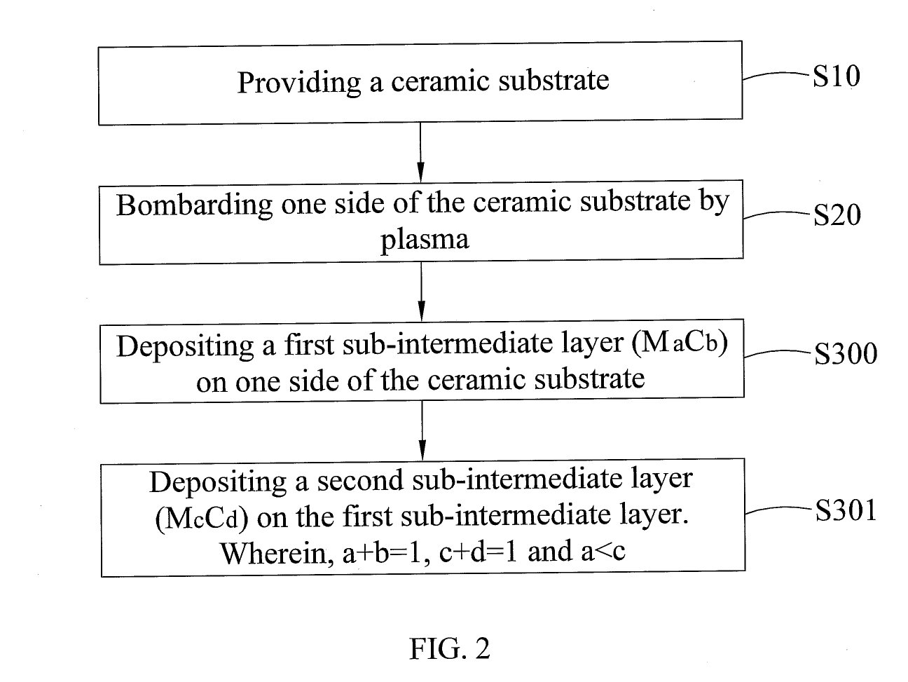

Please refer to FIG. 2, which illustrates another flow chart of the ceramic member manufacturing method thereof in accordance with the present invention. As shown in this figure, the step (S30) of the ceramic member manufacturing method in accordance with the present invention further comprises the steps of:

(S300) depositing a first sub-intermediate layer (MaCb) on one side of the ceramic substrate; and

(S301) depositing a second sub-intermediate layer (M_{c}C_{d}) on the first sub-intermediate layer. Wherein, a+b=1, c+d=1 and a<c.

Wherein, the first intermediate layer and the second intermediate layer can be an oxidized metal (MₐO_{b} or M_{c}O_{d}) or a nitride metal (MₐN_{b} or M_{c}N_{d}). To abbreviate the description, the flow charts of depositing an oxidized metal layer and depositing a nitride metal layer are not shown here.

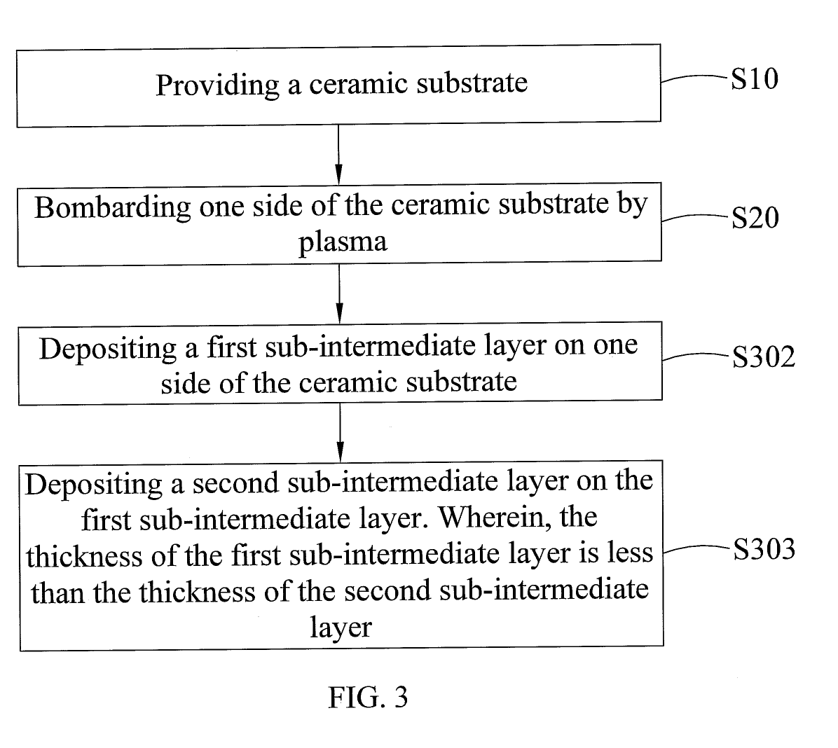

Please refer to FIG. 3, which illustrates another flow chart of the ceramic member manufacturing method in accordance with the present invention. The difference between the present implementation method and the implementation method described above is that in the step (S30), depositing an intermediate layer, could further comprises the following steps of:

(S302) depositing a first sub-intermediate layer on one side of the ceramic substrate; and

(S303) depositing a second sub-intermediate layer on the first sub-intermediate layer. Wherein, the thickness of the first sub-intermediate layer is less than the thickness of the second sub-intermediate layer.

Those of ordinary skilled in the art could easily understand that setting the thickness of the first sub-intermediate layer being higher than the thickness of the second sub-intermediate layer is another embodiment in accordance with the present invention. The figures and illustrations described here should be considered as the example but not limitation.

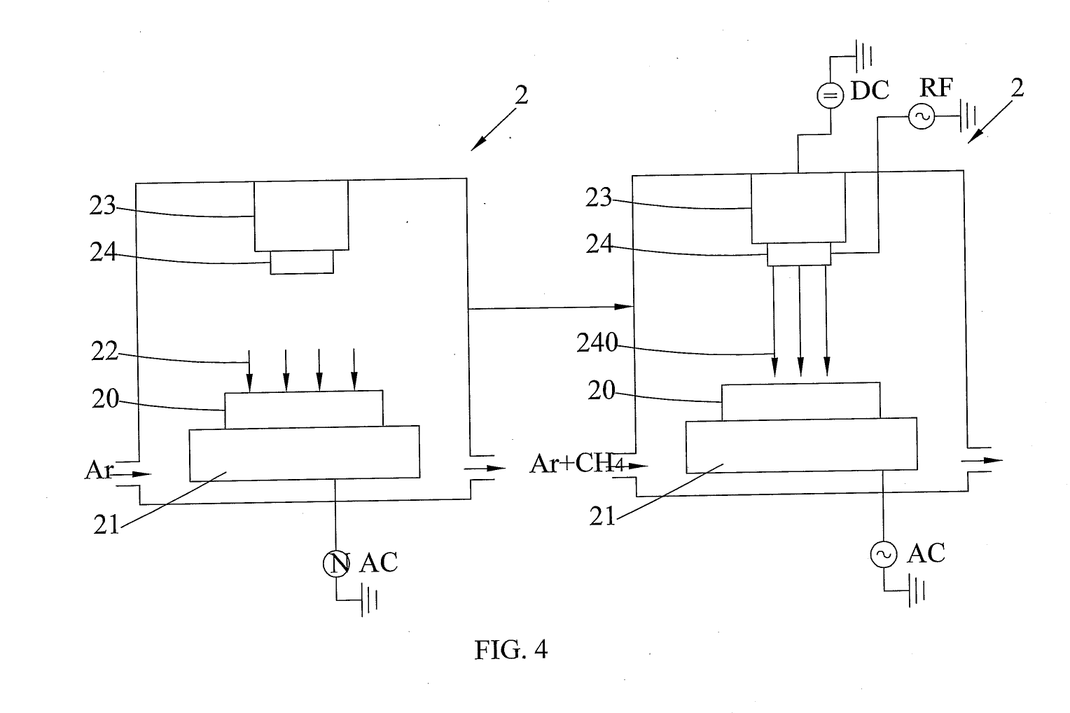

Please refer to FIG. 4, which illustrates a schematic diagram of the ceramic member manufacturing method in accordance with the present invention. As shown on the left side of this figure, a ceramic substrate 20 is set in a sputtering system 2, and is laid on a holder 21, heated to 175˜225° C. After decreasing the working pressure to at least 10⁻⁴ Pa(background pressure), the argon (Ar) is flowed in with 50 mcc/min and then the working pressure is adjusted to 10⁻²˜10⁻³ Pa. Then the holder 21 is given a DC or an AC voltage 15˜35 volt (with 80% power), so as to change the argon to a plasma 22 and bombard the ceramic substrate 20 about 5˜15 minutes as a surface cleaning process.

Then, as shown on the right side of FIG. 4, now the reactive sputtering is processed: injecting in methane, acetylene, other gas having carbon, oxygen or nitrogen as a source of carbon, oxygen or nitrogen in carbonized metal layer, oxidized metal layer or nitride metal layer; giving the sputter gun 23 a DC or an AC voltage (such as RF) 80˜130 volt (40˜85% power) so as to generate the plasma around a target material 24 for sputtering the target material 24, and decreasing the bias power of the ceramic substrate 20 to about 15˜25% at the same time. Wherein, the target material 24 is metal, such as iron, chromium, zinc, tungsten or titanium. At this time, at least one metal atom 240 is sputtered from the target material 24 and moves toward the ceramic substrate 20, and these metal atoms thus chemically react with the plasmarized oxygen, nitrogen and the carbon released from the plasmarized methane, acetylene or other gas having carbon on the metal substrate, and generating a carbonized metal (MₓC_{y}) intermediate layer, an oxidized metal (MₓO_{y}) intermediate layer or a nitride metal (MₓN_{y}) intermediate layer. The intermediate layer could be Fe₃ C, TiO₂, AlN or other different carbonized metals, oxidized metals or nitride metals according to the target materials.

When an intermediate layer with concentration gradient is performed (as shown in step (S21) to step (S22)), the power of the sputtering gun 23, the ratio of argon/carbon source gas, the ratio of argon/oxygen source gas or the ratio of argon/nitrogen source gas is increased with a constant time interval so as to increase the amount of sputtered metal from the target material 24 per unit time, or decreasing the source of carbon, oxygen or nitrogen, and thus raise the metal content in the intermediate layer. Each of the time interval could also be different when increasing the power of the sputtering gun 23 so as to generate an intermediate layer having both concentration and thickness gradient to effectively increase the adhesion of the film.

Finally, providing methane, acetylene or other gas having carbon, oxygen or nitrogen is ceased, such that the source gas of plasma is merely argon. Therefore, there is no chemical reaction on the metal atoms 240 on the ceramic substrate 20, and only a pure metal layer is deposited on the intermediate layer. Besides, the number of the sputtering guns is not limited only one as shown in the figure, there could be a plurality of sputtering guns sputtering same or different metals at the same time or alternately; it is noteworthy that the present is not limited by foregoing sputtering process. This kind of connection method could effectively increase the adhesion between the metal layer and the ceramic substrate 20. In some preferred embodiments, the total thickness of the intermediate layer is 1˜500 nm.

Wherein, the ceramic substrate could be a conventional industrial ceramic substrate such as silicon carbide or aluminum oxide; the voltage provided to the metal target 24 is about 5V˜300V and the power range is about 10%˜85%; the bias voltage provided to the ceramic substrate 20 is about 0˜150V and the power range is about 15%˜90%. The aforementioned operations are dependent on the members to be manufactured, and it is not limited in the present invention.

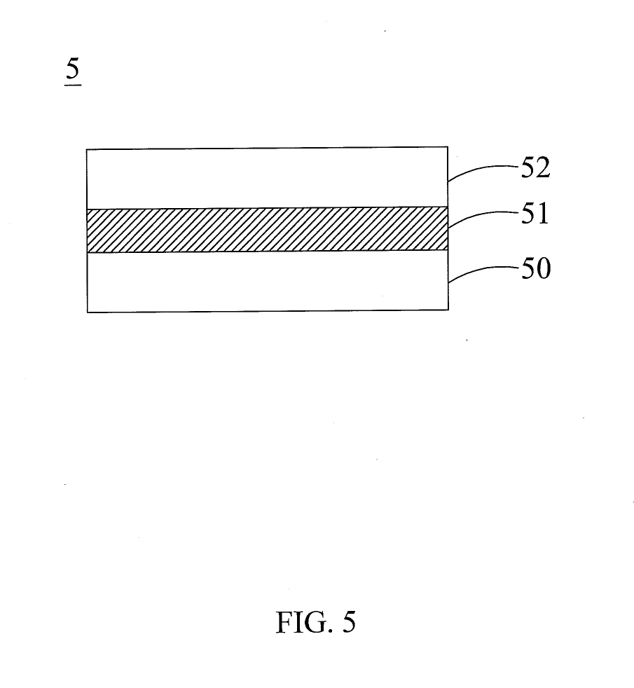

Please refer to FIG. 5, which illustrates a schematic diagram of the first embodiment of the ceramic member in accordance with the present invention. As shown in this figure, the ceramic member 5 in accordance with the present invention comprises a ceramic substrate 50 and an intermediate layer 51. The intermediate layer 51 is disposed on the ceramic substrate 50 by reactively vacuum deposition, and the intermediate layer 51 is a carbonized metal (MₓC_{y}). Wherein, the ceramic substrate 50 could be a commonly used industrial ceramic substrate such as silicon carbide, and the intermediate layer 51 could be a single layer deposited by the aforementioned method. As shown in this embodiment, a metal layer 52 (such as copper and titanium) could further be disposed on the intermediate layer 51, and thus the intermediate layer 51 could effectively connect the metal layer 52 and the ceramic substrate 50.

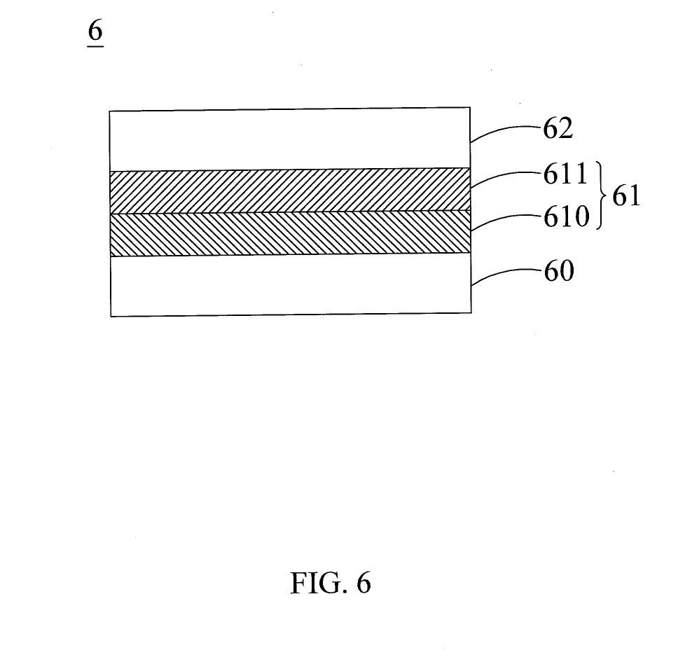

Please refer to FIG. 6, which illustrates a schematic diagram of the second embodiment of the ceramic member in accordance with the present invention. As shown in this figure, the ceramic member 6 in accordance with the present invention comprises a ceramic substrate 60, an intermediate layer 61 and a metal layer 62. The intermediate layer 61 is disposed on the ceramic substrate 60 by reactively vacuum deposition, and the intermediate layer 61 is a carbonized metal (MₓC_{y}); the metal layer 62 is disposed on the intermediate layer 61 by vacuum deposition. In the present embodiment, the intermediate layer 61 further comprises a first sub-intermediate layer 610 and a second sub-intermediate layer 611. The first sub-intermediate layer (MₐC_{b}) 610 is disposed on one side of the ceramic substrate 60, and the second sub-intermediate layer 611 (M_{c}C_{d}) is disposed on the first sub-intermediate layer 610. Wherein, a+b=1, c+d=1 and a<c.

In other words, the present embodiment divides the whole intermediate layer 61 into pluralities of layers with different components, and the metal contain of the upper layer of the intermediate layer 61 is higher. Thus, the ceramic substrate 60 can be connected with the metal layer 62 by a slow and gradual way, such that the stress on the interface could be reduced and the adhesion ability could be increase effectively.

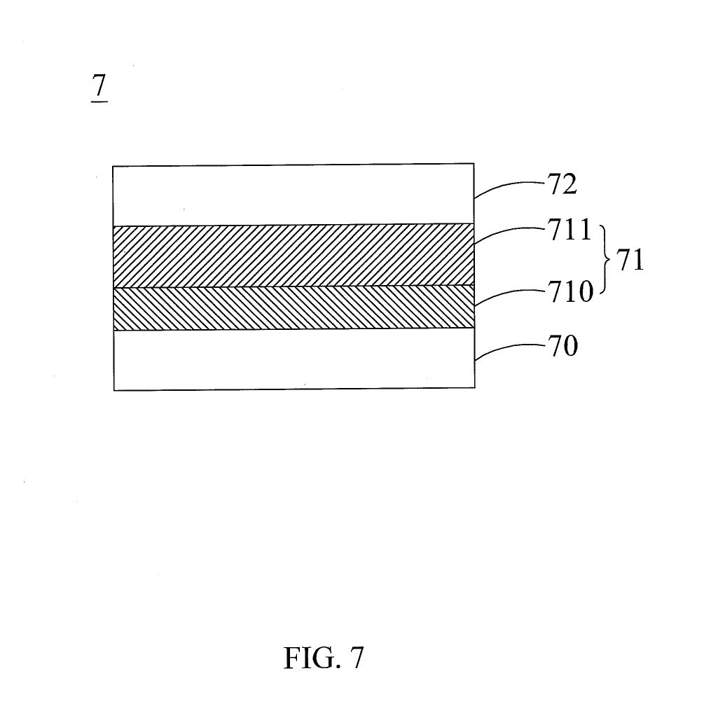

Please refer to FIG. 7, which illustrates a schematic diagram of the third embodiment of the ceramic member in accordance with the present invention. As shown in this figure, the ceramic member 7 in accordance with the present invention comprises a ceramic substrate 70, an intermediate layer 71 and a metal layer 72. The intermediate layer 71 is disposed on the ceramic substrate 70 by reactively vacuum deposition, and the intermediate layer 71 is an oxidized metal (MₓO_{y}), the metal layer 72 is disposed on the intermediate layer 71 by vacuum deposition. In the present embodiment, the intermediate layer 71 further comprises a first sub-intermediate layer 710 and a second sub-intermediate layer 711. The first sub-intermediate layer (MₐO_{b}) 710 is disposed on one side of the ceramic substrate 70, and the second sub-intermediate layer 711 (M_{c}O_{d}) is disposed on the first sub-intermediate layer 710. Wherein, a+b=1, c+d=1 and a<c. In the present embodiment, the thickness of the first sub-intermediate layer 710 is less than the thickness of the second sub-intermediate layer 711. This embodiment gradually changes the thickness and the metal concentration, and thus effectively increases the binding strength.

Besides, a person skilled in the art should know that a sub-intermediate layer using nitride metal as the main content could be deposited by changing oxygen or organic gas in the aforementioned embodiment to nitrogen though it is not shown in this figure. The first sub-intermediate layer could be MₐN_{b} and the second sub-intermediate could be M_{c}N_{d}. The sub-intermediate layer using nitride metal as the main content is another embodiment in accordance with the present invention, and the embodiments, diagrams and illustrations described above are for example but not limitation.

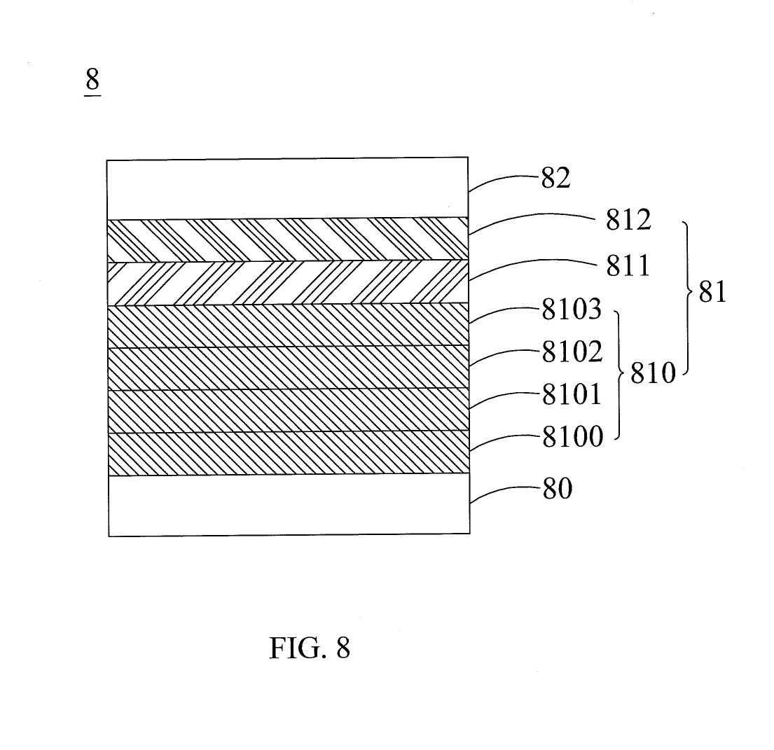

Please refer to FIG. 8, which illustrates a schematic diagram of the fourth embodiment of the ceramic member in accordance with the present invention. As shown in this figure, the ceramic member 8 in accordance with the present invention comprises a ceramic substrate 80, an intermediate layer 81 and a metal layer 82. Wherein, the intermediate layer 81 comprises a carbonized metal intermediate layer 810, a metal intermediate layer 811 and an alloy intermediate layer 812. The carbonized metal intermediate layer 810 comprises a first carbonized metal sub-intermediate 8100, a second carbonized metal sub-intermediate 8101, a third carbonized metal sub-intermediate 8102 and a fourth carbonized metal sub-intermediate 8103. The ceramic member 80 in the present embodiment is silicon carbide. The metal intermediate layer 811 is titanium, and the metal layer 82 is copper.

It is described right here that the first carbonized metal sub-intermediate 8100, the second carbonized metal sub-intermediate 8101, the third carbonized metal sub-intermediate 8102 and the fourth carbonized metal sub-intermediate 8103 are all the sub-intermediate layer described in the aforementioned embodiments, and the structure of the sub-intermediate layer is highly expanded in this embodiment.

In the present embodiment, the ceramic substrate 80 is heated to 175˜255 □ under background pressure, and then the argon is provided with 25˜75 mC.C. Then adjust the working pressure to 10⁻²˜10⁻³ Pa, and the ceramic substrate 80 is provided with substrate bias having 15˜25V and 80% power for about 15˜25 minutes to clean the surface of the substrate. Then acetylene is provided and maintain the argon/acetylene ratio at 2.25, and the sputtering gun is turned on with 75˜90V and 80% power (the bias power of the substrate is decreased to 20%) to sputter the titanium target. The titanium atom is reactively sputtered to the ceramic substrate 80, thus the second carbonized metal sub-intermediate 8100, the titanium carbide (TiₓC_{y}), is formed.

After about 7˜12 minutes, the second carbonized metal sub-intermediate layer 8101 is formed by immediately increasing the argon/acetylene ratio to 2.3. The ratio of y to x in the carbonized titanium (TiₓC_{y}) of the second carbonized metal sub-intermediate 8100 decreases due to the ratio of acetylene provided is relatively decreased. After the same time interval, again increase the argon/acetylene ratio to 3, and further increase the voltage provided to the titanium target sputtering gun to 90˜110 V to further raise the ratio of titanium atom, so as to form the third carbonized metal sub-intermediate layer 8102. Finally, once again increase the argon/acetylene ratio to 6, and further increase the voltage of the titanium target sputtering gun to 100˜130 V to further raise the ratio of titanium atom, thus to form the fourth carbonized metal sub-intermediate layer 8103. The thicknesses of all sub-intermediate layers are all the same due to the constant time interval of sputtering.

After the fourth carbonized metal sub-intermediate layer 8103 is formed, acetylene is closed immediately so as to perform pure titanium sputtering. After the titanium metal layer (the metal intermediate layer 811) with the same thickness is sputtered, another sputtering gun is turned on to sputter the copper target at the same time, and the power and the voltage of two sputtering guns are adjusted to be the same (40%, 100V) and forming a titanium-cupper intermetallic compound or a titanium-copper alloy, the alloy intermediate layer 812, with the same thickness of aforementioned intermediate layer. Afterwards the titanium target sputtering gun is turned off, and only the sputtering gun for sputtering the copper target is left to keep sputtering pure copper in order to form the metal layer 82. Finally, a heat treatment is processed: the metal member 8 is heated to 550-650 □ and kept the same temperature about 10˜15 minutes, and then be cooling down to the room temperature in the furnace.

However, the skilled man in the art should know that an intermediate layer containing oxidized metal or an intermediate layer containing nitride metal could be formed by changing acetylene gas to oxygen or nitrogen. To simplify the description, it will not be stated here again.

In this embodiment, two sets or more than two sets of intermediate layers and sub-intermediate layers are shown, and the metal concentration of these sub-intermediate layers are gradually changed. According to the Cross-Cut Adhesion Test (ASTM D3359, blade interval 1 mm, X-Y 10 grids), the present invention could highly increase the adhesion between the metal layer and the ceramic substrate to more than 4 B and the metal layer is not easy to chap (the adhesion of prior art is about 3 B and is easy to chap). Thus the present invention does increase the adhesion between the metal layer and the ceramic substrate substantially.

In summary, the adhesion between the deposited metal materials and the ceramic substrate could be increased by disposing an intermediate layer between the deposited metal materials and the ceramic substrate, and the problem of the prior art that the deposited metal materials could not fix on the ceramic substrate could be solved by gradually changing the concentration or the thickness of the intermediate layer in accordance with the present invention.

While particular embodiments of the present invention have been shown and described, it will be obvious to those skilled in the art that, based upon the teachings herein, changes and modifications may be made without departing from this invention and its broader aspects. Therefore, the appended claims are intended to encompass within their scope of all such changes and modifications as are within the true spirit and scope of the exemplary embodiment(s) of the present invention.

What is claimed is:

1. A ceramic member, comprising:
a ceramic substrate; and
an intermediate layer, disposed on one side of the ceramic substrate, and the intermediate layer being a carbonized metal (MₓC_{y}), an oxidized metal (MₓO_{y}) or a nitride metal (MₓN_{y}).

2. The ceramic member of claim 1, wherein the intermediate layer further comprises:
a first sub-intermediate layer (MₐC_{b}), disposed on the side of the ceramic substrate; and
a second sub-intermediate layer (M_{c}C_{d}), disposed on the first sub-intermediate;
wherein a+b=1, c+d=1 and a<c.

3. The ceramic member of claim 1, wherein the intermediate layer further comprises:
a first sub-intermediate layer (MₐO_{b}), disposed on the side of the ceramic substrate; and
a second sub-intermediate layer (M_{c}O_{d}), disposed on the first sub-intermediate;
wherein a+b=1, c+d=1 and a<c.

4. The ceramic member of claim 1, wherein the intermediate layer further comprises:
a first sub-intermediate layer (MₐN_{b}), disposed on the side of the ceramic substrate; and
a second sub-intermediate layer (M_{c}N_{d}), disposed on the first sub-intermediate;
wherein, a+b=1, c+d=1 and a<c.

5. The ceramic member of claim 1, wherein the intermediate layer further comprises:
a first sub-intermediate layer, disposed on the side of the ceramic substrate; and
a second sub-intermediate layer, disposed on the first sub-intermediate;
wherein, the thickness of the first sub-intermediate layer is less than the thickness of the second sub-intermediate layer.

6. The ceramic member of claim 1, wherein the intermediate layer further comprises:
a first sub-intermediate layer, disposed on the side of the ceramic substrate; and
a second sub-intermediate layer, disposed on the first sub-intermediate;
wherein, the thickness of the first sub-intermediate layer is higher than the thickness of the second sub-intermediate layer.

7. The ceramic member of claim 1, wherein the thickness of the intermediate layer is 1˜500 nm.

8. The ceramic member of claim 1, wherein the ceramic member further comprises a metal layer disposed on the intermediate layer.

9. A ceramic member manufacturing method, comprising the steps of:
providing a ceramic substrate;
bombarding one side of the ceramic substrate by plasma; and
depositing an intermediate layer on the side of the ceramic substrate by reactively vacuum deposition, and the intermediate layer being a carbonized metal (MₓC_{y}), an oxidized metal (MₓO_{y}) or a nitride metal (MₓN_{y}).

10. The ceramic member manufacturing method of claim 9, wherein the step of depositing the intermediate layer further comprises:
depositing a first sub-intermediate layer (MₐC_{b}) on the side of the ceramic substrate; and
depositing a second sub-intermediate layer (M_{c}C_{d}) on the first sub-intermediate layer;
wherein, a+b=1, c+d=1 and a<c.

11. The ceramic member manufacturing method of claim 9, wherein the step of depositing the intermediate layer further comprises:
depositing a first sub-intermediate layer (MₐO_{b}) on the side of the ceramic substrate; and
depositing a second sub-intermediate layer (M_{c}O_{d}) on the first sub-intermediate layer;
wherein, a+b=1, c+d=1 and a<c.

12. The ceramic member manufacturing method of claim 9, wherein the step of depositing the intermediate layer further comprises:
depositing a first sub-intermediate layer (MₐN_{b}) on the side of the ceramic substrate; and
depositing a second sub-intermediate layer (M_{c}N_{d}) on the first sub-intermediate layer;
wherein, a+b=1, c+d=1 and a<c.

13. The ceramic member manufacturing method of claim 9, wherein the step of depositing the intermediate layer further comprises:
depositing a first sub-intermediate layer on the side of the ceramic substrate; and
depositing a second sub-intermediate layer on the first sub-intermediate layer; wherein, the thickness of the first sub-intermediate layer is less than the thickness of the second sub-intermediate layer.

14. The ceramic member manufacturing method of claim 9, wherein the step of depositing the intermediate layer further comprises:
depositing a first sub-intermediate layer on the side of the ceramic substrate; and
depositing a second sub-intermediate layer on the first sub-intermediate layer; wherein, the thickness of the first sub-intermediate layer is higher than the thickness of the second sub-intermediate layer.

15. The ceramic member manufacturing method of claim 9, wherein the working pressure of the plasma bombardment and the vacuum deposition is 10-2˜10-4 Pa.

16. The ceramic member manufacturing method of claim 9, wherein argon, organic gas, oxygen, nitrogen or a mixture of at least two gases mentioned is provided as the plasma gas during the vacuum deposition.

17. The ceramic member manufacturing method of claim 16, wherein the organic gas is methane or acetylene.

18. The ceramic member manufacturing method of claim 9, wherein the thickness of the intermediate layer is 1˜500 nm.

19. The ceramic member manufacturing method of claim 9, wherein the method further comprises the step of:
depositing a metal layer on the intermediate layer by vacuum deposition.
